(19) United States
(12) Patent Application Publication
(10) Pub. No.: US 2008/0309388 A1
(43) Pub. Date: Dec. 18, 2008

(54) METHOD FOR ADJUSTING PHASE RELATIONSHIP BETWEEN SIGNALS IN A MEASURING APPARATUS, AND A MEASURING APPARATUS

(75) Inventors: Tomoki Hashimoto, Hyogo (JP); Tomoo Konishi, Hyogo (JP)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(73) Assignee: AGILENT TECHNOLOGIES, INC., Santa Clara, CA (US)

(21) Appl. No.: 12/122,372

(22) Filed: May 16, 2008

(30) Foreign Application Priority Data
Jun. 15, 2007 (JP) 2007-158459

(51) Int. Cl. H03L 7/00

(52) U.S. Cl. 327/161; 327/141

(57) ABSTRACT

A measuring apparatus having a frequency-swept heterodyne-type frequency converter equipped with a frequency-swept signal source and a multiplier includes means for detecting the timing of reference burst signals that have been subjected to frequency conversion by the frequency converter, with the frequency of the output signals of the frequency-swept signal source locked; means for generating periodic pulse signals; and means for adjusting the phase relationship between the pulse signals and the reference burst signals using the detected timing; and means for sweeping the frequency of the output signals of the frequency-swept signal source using pulse signals that have been subjected to a phase relationship adjustment.

The disclosed embodiments relate to technology for measuring burst signals in a frequency-swept heterodyne-type measuring apparatus. The frequency-swept heterodyne-type measuring apparatus is an apparatus with which signals under test that are input are converted to different frequencies and measured. This apparatus sweeps the frequency of local signals used for frequency conversion.

### BACKGROUND

When measuring signals in burst form using a frequency-swept heterodyne-type measuring apparatus such as a spectrum analyzer, it is necessary to know the temporal position occupied by these signals in burst form. This is because the frequency sweep of local signals and the measurement of reference signals are performed only during the period when the signals in burst form are present. The signals in burst form are simply referred to as burst signals hereafter. The following three methods are typical conventional methods for determining the temporal position occupied by burst signals.

The first method is the method whereby signals for which the temporal position occupied by burst signals is known are transmitted to the measuring apparatus from an outside measuring apparatus (see for example: JP (Kokai) Unexamined Patent Publication-5-60809, page 3, FIG. 1; JP (Jitsuyo) Utility Model 6-342022, pages 2 and 3, FIG. 2; Operating and Service Guide, Agilent Technologies, 85902A, Burst Carrier Trigger and RF Preamplifier, US. Agilent Technologies, Inc., January, 2000, p. 36-37). In this case, a frequency sweep of local signals and a measurement of reference signals that have been subjected to frequency conversion are performed in synchronization with the transmitted signals in the measuring apparatus. For example, the frequency sweeping and the measurement are performed when the external signals are at logic level H (High), and the frequency sweeping and the measurement are stopped when external signals are at logic level L (Low).

The second method is the method whereby repeating signals are generated by the measuring apparatus when burst signals are being repeated (see for example, (Jitsuyo) Utility Model 4-106771, FIGS. 1 and 2). In this case, the measuring apparatus performs a frequency sweep of local signals and a measurement of reference signals that have been subjected to frequency conversion in synchronization with the repeating signals generated by the measuring apparatus. The third method is the method whereby the temporal position occupied by burst signals having a single frequency is detected by the measuring apparatus based on the reference signals (See for example, JP (Jitsuyo) Utility Model 7-14389, FIGS. 1, 2, and 3). In further detail, the measuring apparatus converts the frequency of the reference signals that are input, filters the frequency conversion results using an IF filter that determines the resolution bandwidth, performs an envelope detection of the filtration results, and adjusts the waveform of detection results. Thus, rectangular waveform signals showing the temporal position occupied by burst signals is obtained. The measuring apparatus performs a frequency sweep of local signals and a measurement of the frequency-converted reference signals in synchronization with these rectangular waveform signals.

However, the first method cannot be used unless signals for which the temporal position occupied by burst signals is known are provided by the apparatus that outputs the reference signals. Moreover, the second method requires that in order to align the phase of the repeating signals generated by the measuring apparatus and the phase of the burst signals, either these phases are adjusted manually, or external signals for adjusting the phase are input into the measuring apparatus. Moreover, the synchronized state is maintained for only a short time when there is a difference between the frequency of the repeating signals generated by the measuring apparatus and the frequency of the burst signals. Furthermore, the third method is not suitable for modulated signals in burst form. The phrase “modulated signals” means signals that have been modulated. Modulated signals occupy a broader bandwidth than do single-frequency signals. The modulated signals that have passed through an IF filter will be distorted if the band region occupied by the modulated signals is not within the pass band region of the IF filter, which determines the resolution bandwidth. As a result, the above-mentioned rectangular waveform signals will not correctly represent the temporal position occupied by the burst signals.

### SUMMARY

The disclosed embodiments provide technology for measuring modulated signals in burst form without inputting signals other than reference signals and without manually adjusting the phase in a frequency-swept heterodyne-type measuring apparatus.

At least one embodiment includes a method for adjusting the phase relationship between reference burst signals and the periodic pulse signals generated within a measuring apparatus having a frequency-swept heterodyne-type frequency converter equipped with a frequency-swept signal source and a multiplier, characterized in comprising a first step for locking the frequency of the output signals of the frequency-swept signal source; a second step for detecting the timing of the reference burst signals that have been subjected to frequency conversion by the frequency converter; and a third step for adjusting the phase relationship between the pulse signals and the reference burst signals using the detected timing.

The method may include initiating pulse signal generation in response to the detected timing.

The method may also include applying a delay to the pulse signals, reference burst signals, or converted reference burst signals in accordance with the time difference between the detected timing and the pulse signals.

The method may further include locking the frequency of the output signals of the frequency-swept signal source at the frequency corresponding to the center frequency of the reference burst signals.

The fifth invention is the method according to any of the first, second, third, or fourth inventions, further characterized in that the third step is performed for every sweep within the measurement frequency range.

The sixth invention is a measuring apparatus having a frequency-swept heterodyne-type frequency converter equipped with a frequency-swept signal source and a multiplier, characterized in comprising means for detecting the timing of reference burst signals that have been subjected to frequency conversion by the frequency converter, with the frequency of the output signals of the frequency-swept signal source locked; means for generating periodic pulse signals; means for adjusting the phase relationship between the pulse signals and the reference burst signals using the detected timing; and means for sweeping the frequency of the output signals of the frequency-swept signal source using pulse signals that have been subjected to a phase relationship adjustment.

The seventh invention is the apparatus according to the sixth invention, further characterized in that the phase relationship adjustment means adjusts the phase relationship by allowing the pulse signal generation means to initiate the generation of pulse signals in response to the detected timing.

The eighth invention is the apparatus according to the sixth invention, further characterized in that the phase relationship adjustment means adjusts the phase relationship by applying a delay to the pulse signals, reference burst signals, or converted reference burst signals in accordance with the time difference between the pulse signals and the detected timing.

The ninth invention is the apparatus according to any of the sixth, seventh, or eighth inventions, further characterized in that the timing detection means detects the timing of the reference burst signals that have been subjected to frequency conversion, with the frequency of the output signals of the frequency-swept signal source locked at the frequency corresponding to the center frequency of the reference burst signals.

The tenth invention is the apparatus according to any of the sixth, seventh, eighth, or ninth inventions, further characterized in that the phase relationship adjustment means adjusts the phase relationship for each sweep of the measurement frequency range.

By means of the disclosed embodiments, it is possible to measure any portion of modulated signals in burst form more accurately than in the past without inputting signals other than reference signals and without manual phase adjustment in a frequency-swept heterodyne-type measuring apparatus.

### BRIEF DESCRIPTION OF THE DRAWINGS

FIG. 1 is a drawing showing the structure of a first spectrum analyzer according to the disclosed embodiments.

FIG. 2 is a timing chart of the signals inside the spectrum analyzer.

FIG. 3 is a drawing showing the structure of a second spectrum analyzer according to another embodiment.

FIG. 4 is a timing chart of the signals inside the second spectrum analyzer.

FIG. 5 is a drawing showing the structure of a third spectrum analyzer, which is a modification of the first spectrum analyzer.

### DETAILED DESCRIPTION

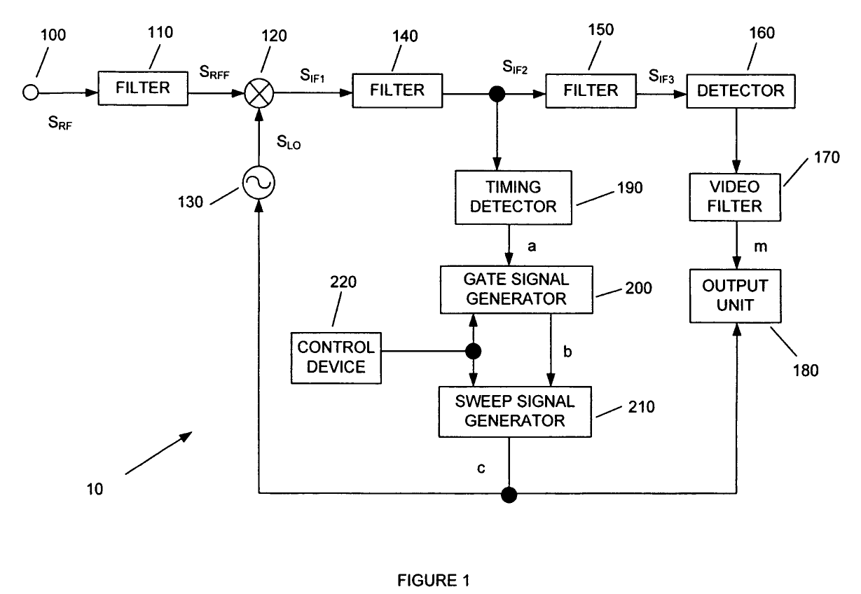

Exemplary embodiments will be described below while referring to the attached drawings. Refer to FIG. 1. FIG. 1 shows the internal structure of a spectrum-analyzer 10. The internal structure of spectrum analyzer 10 will be described.

Spectrum analyzer 10 in FIG. 1 comprises an input terminal 100, a filter 110, a mixer 120, a frequency-swept signal source 130, a filter 140, a filter 150, a detector 160, a video filter 170, an output apparatus 180, a timing detector 190, a gate signal generator 200, a sweep signal generator 210, and a control device 220.

Input terminal 100 is a terminal for receiving reference signals S_{RF}. By means of the present embodiment, modulation signals in burst form are received as reference signals S_{RF}. Filter 110 comprises a low-pass filter or band-pass filter, and acts at least as an image filter. Filter 110 filters reference signals S_{RF} and outputs the filtration result (S_{RFF}). Mixer 120 acts as a multiplier. Mixer 120 multiplies the output signals S_{RFF} of filter 110 and output signals S_{LO} of frequency-swept signal source 130 and outputs the multiplication result S_{IF1}. Multiplication result S_{IF1} comprises the sum frequency component and the difference frequency component of signal S_{RFF} and signal S_{LO}. Filter 140 is a filter that allows the passage of one frequency component of the sum and the difference frequency component but blocks the other frequency component. In the present specification, filter 140 is a low-pass filter or band-pass filter that allows the passage of the difference frequency component but blocks the sum frequency component. Consequently, the combination of mixer 120, frequency-swept signal source 130, and filter 140 serves as a down converter.

Filter 150 is a filter for determining the frequency resolution of spectrum analyzer 10. The filter that determines frequency resolution is hereafter called the resolution bandwidth filter. Filter 140 and filter 150 are called IF filters. The output signal S_{IF3} of filter 150 is detected by detector 160 and further temporally averaged by video filter 170 and supplied to output unit 180. As is already known, the output signal m of video filter 170 represents the results of spectrum analysis of reference signal S_{RF}. Output unit 180 for reference signal S_{RF} is the apparatus for outputting measurement result m. Output unit 180, for instance, is a display, printer, or network. It should be noted that a memory for holding the measurement results m (not illustrated) can be used in place of output unit 180 or in addition to output unit 180. Moreover, a log amplification circuit (not illustrated) can also be inserted in front of or behind detector 160 as needed.

Timing detector 190 is the apparatus for detecting the temporal position occupied by burst signals from output signal S_{IF2} of filter 140. Timing detector 190 subjects the output signal S_{IF2} of filter 140 to envelope detection and generates a signal a showing the temporal position occupied by the burst signals by comparing the detection results to a predetermined level. This predetermined level is set as needed by the user of spectrum analyzer 10. Generated signal a is fed from timing detector 190 to gate signal generator 200. In the present Specification, binary signals are generated and output by timing detector 190. Moreover, the logic level of these binary signals is high (H) when burst signals are present and low (L) when burst signals are not present. It should be noted that the detection method of timing detector 190 can be another detection method as long as it is possible to recognize changes in the power level of output signals S_{IF2} of filter 140 based on the results of this detection. For instance, it is possible to use effective value detection, and similar methods. Moreover, it is also possible to use the edge in place of the logic level in order to determine the temporal position occupied by burst signals.

Gate signal generator 200 is an apparatus for generating a gate signal b, which is a periodic binary pulse signal, in accordance with signal a. Sweep signal generator 210 is an apparatus for generating signals c for controlling the frequency f_{LO} of output signals S_{LO} of frequency-swept signal source 130. In other words, sweep signal generator 210 acts as a control apparatus for frequency-swept signal source 130. Frequency-swept signal source 130 changes the frequency of output signals S_{LO} in accordance with the level of the input signals. By means of the present specification, frequency f_{LO} increases with an increase in the level of the signals input to frequency-swept signal source 130, and frequency f_{LO} decreases as the same input signal level becomes smaller. The level of output signal c of sweep signal generator 210 sweeps a predetermined level range such that frequency f_{LO} sweeps a predetermined frequency range. By means of the present embodiment, the level of output signals c sweeps when the logic level of gate signals b is high (H), and remains constant when the logic level of gate signals b is low (L). In other words, when the logic level of gate signals b is high (H), frequency f_{LO} sweeps, and when the logic level of gate signals b is low (L), frequency f_{LO} becomes constant. Signal c can be a digital signal or an analog signal. Control device 220 is a device for controlling each of the structural elements of spectrum analyzer 10. Portions of the control lines between control apparatus 220 and each structural element of spectrum analyzer 10 are omitted in FIG. 1.

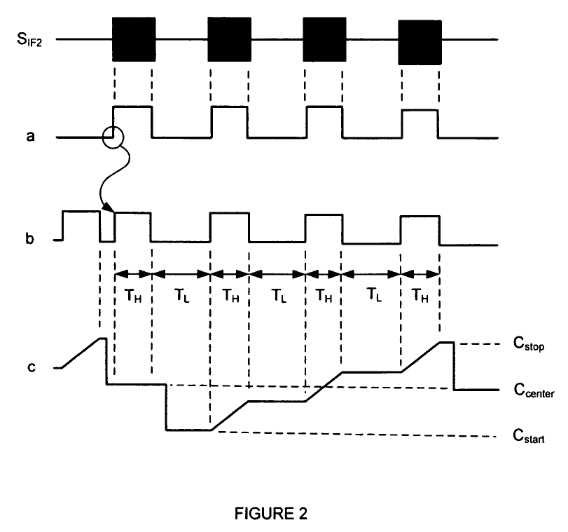

The procedure for measuring the burst signals of spectrum analyzer 10 will now be described. Refer to FIG. 1 and FIG. 2. FIG. 2 is a drawing showing the timing chart of signal S_{IF2}, signal a, signal b, and signal c. The y-axis of the timing chart in FIG. 2 represents the level, while the x-axis represents time.

First, the phases of the burst signals contained in signal S_{IF2} and gate signal b are aligned. Specifically, the first frequency sweep of output signals S_{LO} Of frequency-swept signal source 130 is stopped under the control of control device 220. In this case, frequency f_{LO} of signal S_{LO} is fixed at the frequency corresponding to the center frequency of reference signals S_{RF}. Moreover, the output signal c of sweep signal generator 210 is fixed at a level C_{center} corresponding to the center frequency of reference signals S_{RF}. By means of this embodiment, the center frequency of reference signal S_{RF} is the same as the center frequency within the measurement frequency range prescribed in advance for spectrum analysis of reference signal S_{RF}. For instance, the measurement frequency range of spectrum analyzer 10 is between 1 GHz and 3 GHz, and when the center frequency of filter 150 is 10 MHz, frequency f_{LO} of signal S_{LO} is swept between (0.99 GHz=1 GHz−10 MHz) and (2.99 GHz=3 GHz−10 MHz). Consequently, in this case, frequency f_{LO} of signal S_{LO} is fixed at (1.99 GHz=2 GHz−10 MHz).

Once frequency f_{LO} of signal S_{LO} has been fixed, the phase relationship between reference signal S_{RF} and gate signal b is adjusted. Specifically, gate signal generator 200 synchronizes gate signal b with signal S_{IF2} by initiating the generation of periodic binary pulse signals in response to the positive edge of signal S_{IF2}. As shown in FIG. 2, the timing of gate signal b thus far is disregarded and the generation of periodic binary pulse signals is newly initiated in response to the positive edge of signals S_{IF2}. It should be noted that the parameters of the periodic binary pulse signals are preset at a value as needed, or at a value according to WiMax, or another standards. By means of the present embodiment, pulse signal parameters are given such that logic level High (H) is manifested in time T_{H} immediately after signal generation is initiated, and then logic level low (L) is manifested in time T_{L}. Time T_{H} is equal to the burst duration time in signal S_{IF2}, and (T_{H}+T_{L}) is equal to the repeat period of the burst of signal S_{IF2}. Once synchronized, gate signal generator 200 repeatedly generates binary pulses in accordance with given parameters until it is controlled again by control device 220.

Finally, reference signal S_{RF} is measured. Once gate signal b has been synchronized with signal S_{IF2}, sweep signal generator 210 begins to sweep the level of signal c under the control of control device 220. This level sweep is performed within the level range that corresponds to the measurement frequency range specified in advance for spectrum analysis of the reference signal S_{RF}. In essence, a level sweep is performed, from the sweep start level cₛₜₐᵣₜ corresponding to one end of the measurement frequency range to the sweep stop level cₛₜₒₚ corresponding to another end of the measurement frequency range. Moreover, as previously mentioned, the level of output signal c of sweep signal generator 210 is swept in accordance with the logic level of gate signal b. Consequently, frequency f_{LO} of signal S_{LO} is swept while the logic level of gate signal b is high (H), and the spectrum analysis result m is reflected by output unit 180. Thus, the spectrum analysis result for the burst segment of the reference signal S_{RF} is obtained.

In terms of more precise measurements, the adjustment of the phase relationship between reference signal S_{RF} and gate signal b preferably is repeated for at least each sweep of the entire measurement frequency range. By means of the present embodiment, each time the level of signal c reaches the sweep stop level cₛₜₒₚ, a synchronization of gate signal b is performed at least once before starting a new sweep from sweep start level cₛₜₐᵣₜ of the level of signal c. The preceding has been a description of the first embodiment.

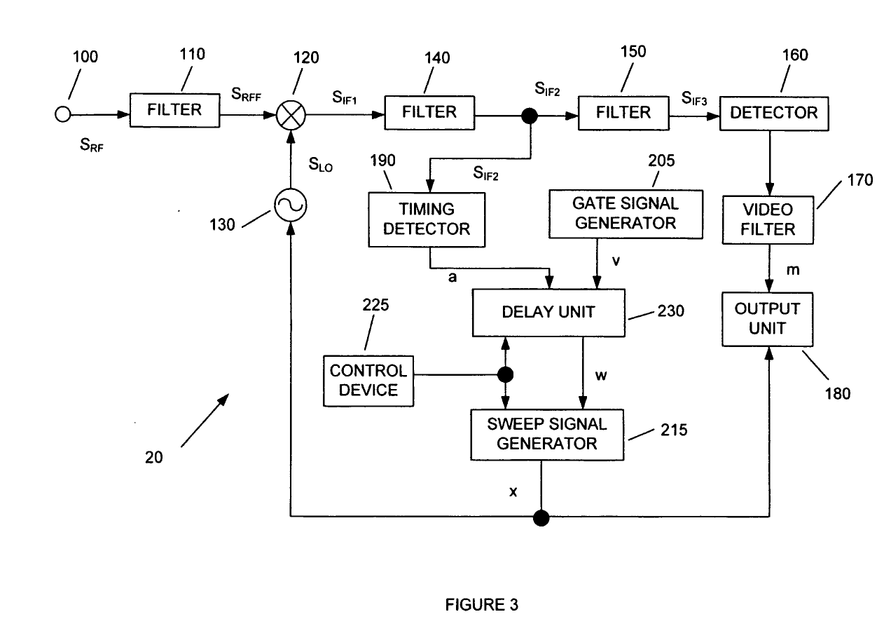

Next, other embodiments will be described below while referring to the attached drawings. Refer to FIG. 3. FIG. 3 shows the internal structure of spectrum analyzer 20. Spectrum analyzer 20 is different from spectrum analyzer 10 in terms of its gate signal synchronization. In FIG. 3, the same reference numerals are used for the same elements as in FIG. 1 and a detailed description is omitted for the elements. First, the internal structure of spectrum analyzer 20 will be described.

Spectrum analyzer 20 comprises a gate signal generator 205, a sweep signal generator 215, a control apparatus 225, and a delay apparatus 230 in place of gate signal generator 200, sweep signal generator 210, and control apparatus 220.

Gate signal generator 205 is an apparatus for generating gate signals v, which are periodic binary pulse signals. The parameters of the periodic binary pulse signals are set in advance at any value as needed or at a value according to WiMax, or another standard. By means of the present embodiment, pulse signal parameters are given such that logic level High (H) is manifested in time T_{H} immediately after the signal generation is initiated, and then logic level low (L) is manifested in time T_{L}. Delay unit 230 is a device for applying delay to gate signals v. A gate signal w, which is the result of delaying gate signal v, is supplied to sweep signal generator 215. Sweep signal generator 215 is the device that generates signal x for controlling frequency f_{LO} of output signal S_{LO} of frequency-swept signal source 130. The level of output signal x of sweep signal generator 215 sweeps a predetermined level range such that frequency f_{LO} of output signal S_{LO} of frequency-swept signal source 130 sweeps a predetermined frequency range. In other words, sweep signal generator 215 functions as a control device for frequency-swept signal source 130. By means of the present embodiment, the level of output signal x sweeps when the logic level of gate signal w is high (H) and remains constant when the logic level of gate signal w is low (L). It should be noted that signal x can be a digital signal or an analog signal. Control device 225 is a device for controlling each structural element of spectrum analyzer 20. Portions of the control lines between control device 225 and each of the structural elements of spectrum analyzer 20 are omitted in FIG. 3.

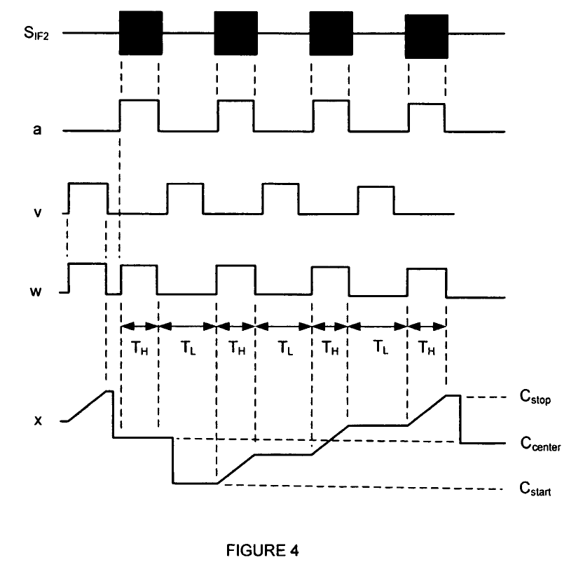

Next, the procedure for measuring the burst signals in spectrum analyzer 20 will be described. Refer to FIGS. 3 and 4. FIG. 4 is a drawing showing an example of the timing chart of signal S_{IF2}, signal a, signal v, signal w, and signal x. The y-axis of the timing chart in FIG. 4 represents the level and the x-axis represents time.

First, the phases of the burst signals contained in signal S_{IF2} and gate signal v are aligned. Specifically, the first frequency sweep of output signals S_{LO} of frequency-swept signal source 130 is stopped by control device 225. In this case, frequency f_{LO} of signal S_{LO} is held at the frequency corresponding to the center frequency of reference signals S_{RF}. Moreover, output signal x of sweep signal generator 215 is held at level C_{center} corresponding to the center frequency of reference signals S_{RF}. By means of this embodiment, the center frequency of reference signal S_{RF} is the same as the center frequency within the measurement frequency range prescribed in advance for the spectrum analysis of reference signal S_{RF}.

Once the frequency f_{LO} of signal S_{LO} has been fixed, the phase relationship between reference signal S_{RF} and gate signal w is adjusted. Specifically, delay unit 230 synchronizes gate signal w with signal S_{IF2} by applying a delay to gate signal v under the control of control device 225. In this case, for instance, the delay is determined based on output signal a and gate signal v such that the phase of output signal a and the phase of gate signal w are the same, and the determined delay is applied to gate signal v. Once delay unit 230 has synchronized the phase of output signal a and the phase of gate signal w, it continues to apply the same delay to gate signal v until it is controlled again by control device 225.

Finally, reference signal S_{RF} is measured. Once gate signal w is synchronized with signal S_{IF2}, sweep signal generator 215 initiates a level sweep under the control of control device 225. This level sweep is performed within the level range corresponding to the measurement frequency range specified in advance for the spectrum analysis of reference signal S_{RF}. In essence, level sweeping is performed from the sweep start level cₛₜₐᵣₜ corresponding to one end of the measurement frequency range to sweep stop level cₛₜₒₚ corresponding to the other end of the measurement frequency range. The level of output signal x of sweep signal generator 215 is swept in accordance with the logic level of gate signal w. Consequently, frequency f_{LO} of signal S_{LO} is swept while the logic level of gate signal w is high (H), and the spectrum analysis result m is reflected by output unit 180. Thus, a spectrum analysis result is obtained for the burst segment of reference signal S_{RF}.

In terms of more precise measurements, the adjustment of the phase relationship between reference signal S_{RF} and gate signal w preferably is repeated for at least each sweep of the entire measurement frequency range. By means of the second embodiment, each time the level of signal x reaches the sweep stop level cₛₜₒₚ, the delay to be applied to gate signal v is determined at least once before starting a new sweep from sweep start level cₛₜₐᵣₜ of the level of signal x.

By means of the second embodiment, it is enough to adjust the phase relationship between gate signal w and signal S_{IF2}. Consequently, it is possible to apply a delay to the reference signals, such as signal S_{RF}, signal S_{RFF}, and signal S_{IF2}, rather than to apply a delay to gate signal v. Moreover, a delay can be applied to both gate signal v and the reference signals. The preceding has been a description of the second embodiment.

The first and second embodiments can be modified as described below. First, by means of the first and second embodiments, time T_{H} equal to the burst duration time is provided as a pulse signal parameter in order to measure the entire burst segment of signal S_{IF2}. By means of the first and second embodiments, it is also possible to provide a signal parameter such that the time for which logic level high (H) persists is shorter than T_{H}, in order to measure a specific portion of the burst segment of signal S_{IF2}. In this case, the timing of the signal generation by gate signal generator 200 and the delay to be applied by delay unit 230 are adjusted such that the logic level high (H) component of signal b or signal w corresponds to the specific portion of the burst segment of signal S_{IF2}. Of course, even in this case, the standard is the temporal position occupied by the burst signal as detected with a frequency sweep of signal S_{Lo} locked.

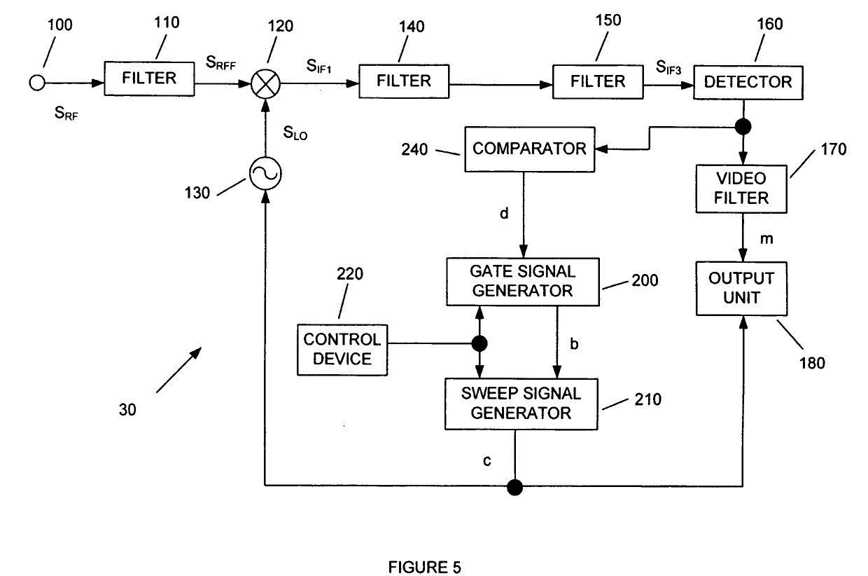

Moreover, by means of the first and second embodiments, the temporal position in signal S_{IF2} occupied by the burst signal is detected. When the modulation band of the burst signal is enclosed by the passband of filter 150, it is also possible to detect the temporal position occupied by the burst signal based on signal S_{IF3} and the output signals of detector 160. In this case, for instance, spectrum analyzer 10 shown in FIG. 1 is modified as spectrum analyzer 30 in FIG. 5. In FIG. 5, signal d supplied to gate signal generator 200 is generated when a comparator 240 compares the output signal of detector 160 with a predetermined level. It should be noted that this predetermined level is set as needed by the user of spectrum analyzer 30. Moreover, when the detection system used by the timing detector in FIG. 1 is the same as the detection system used by detector 160, signal d is substantially the same. The procedure for measuring the burst signal is the same as the procedure in spectrum analyzer 10, with the exception that signal a is replace by signal d.

By means of the first and second embodiments, the passband of filter 140 can be narrowed to the band of reference burst signal S_{RF}. When detecting the timing of the burst, frequency f_{Lo} of signal S_{Lo} is locked at the frequency corresponding to the center frequency of reference burst signal S_{RF}; therefore, the burst waveform of signal S_{IF2} is not distorted, even if the passband of filter 140 becomes narrower. As a result, the noise component contained in signal S_{IF2} can be controlled and the accuracy of detecting the burst timing is increased.

By means of the first and second embodiments, it is possible to create each of the structural elements inside the spectrum analyzer using hardware, or they can be virtually created as a result of a processor executing software. For instance, an analog-digital converter for digitizing reference signal S_{RF} and a processor for processing the digital reference signal S_{RF} can be replaced for all of the structural elements of spectrum analyzer 10 shown in FIG. 1.

The presently disclosed embodiments may also be used to measure burst signals using a network analyzer or other frequency-swept heterodyne-type measuring apparatus.

The reference numbers used in the drawings include the following:
10, 20, 30 Spectrum analyzers
100 Input terminal
110, 140, 150 Filters
120 Mixer
130 Frequency-swept signal source
160 Detector
170 Video filter
180 Output unit
190 Timing detector
200, 205 Gate signal generators
210, 215 Sweep signal generators
220, 225 Control devices
230 Delay unit
240 Comparator

1. A method for adjusting the phase relationship between reference burst signals and periodic pulse signals generated within a measuring apparatus having a frequency-swept heterodyne-type frequency converter equipped with a frequency-swept signal source and a multiplier, said method comprising:
locking the frequency of the output signals of the frequency-swept signal source;
detecting the timing of the reference burst signals that have been subjected to frequency conversion by the frequency converter; and
adjusting the phase relationship between the pulse signals and the reference burst signals using the detected timing.

2. The method according to claim 1, wherein adjusting the phase relationship between the pulse signals and the reference burst signals includes initiating a pulse signal generation in response to the detected timing.

3. The method according to claim 1, wherein adjusting the phase relationship between the pulse signals and the reference burst signals includes applying a delay to the pulse signals, reference burst signals, or converted reference burst signals in accordance with the time difference between the detected timing and the pulse signals.

4. The method according to claim 1, wherein locking the frequency of the output signals of the frequency-swept signal source includes locking the frequency of the output signals of the frequency-swept signal source at a frequency corresponding to the center frequency of the reference burst signals.

5. The method according to claim 1, wherein adjusting the phase relationship between the pulse signals and the reference burst signals is performed for every sweep within the measurement frequency range.

6. A measuring apparatus having a frequency-swept heterodyne-type frequency converter equipped with a frequency-swept signal source and a multiplier, said apparatus comprising
means for detecting the timing of reference burst signals that have been subjected to frequency conversion by the frequency converter, with the frequency of the output signals of the frequency-swept signal source locked;
means for generating periodic pulse signals;
means for adjusting the phase relationship between the pulse signals and the reference burst signals using the detected timing; and means for sweeping the frequency of the output signals of the frequency-swept signal source using pulse signals that have been subjected to a phase relationship adjustment.

7. The measuring apparatus according to claim 6, wherein the phase relationship adjustment means adjusts the phase relationship by allowing the pulse signal generation means to initiate the generation of pulse signals in response to the detected timing.

8. The measuring apparatus according to claim 6, wherein the phase relationship adjustment means adjusts the phase relationship by applying a delay to the pulse signals, reference burst signals, or converted reference burst signals in accordance with the time difference between the pulse signals and the detected timing.

9. The measuring apparatus according to claims 6, wherein the timing detection means detects the timing of the reference burst signals that have been subjected to frequency conversion, with the frequency of the output signals of the frequency-swept signal source locked at the frequency corresponding to the center frequency of the reference burst signals.

10. The measuring apparatus according to claims 6, wherein the phase relationship adjustment means adjusts the phase relationship with each sweep of the measurement frequency range.
